(19) United States
(12) Patent Application Publication
(10) Pub. No.: US 2024/0105664 A1
(43) Pub. Date: Mar. 28, 2024

(54) PACKAGE STRUCTURE AND METHOD OF MANUFACTURING THE SAME

(71) Applicant: CHIPBOND TECHNOLOGY CORPORATION, Hsinchu (TW)

(72) Inventors: Yu-Chung Huang, Hsinchu City (TW); Hsin-Yen Tsai, Taichung City (TW); Fa-Chung Chen, Hsinchu County (TW); Cheng-Fan Lin, Hsinchu County (TW); Chen-Yu Wang, Hsinchu City (TW)

(21) Appl. No.: 18/234,645

(22) Filed: Aug. 16, 2023

(30) Foreign Application Priority Data
Sep. 22, 2022 (TW) 111135998

(51) Int. Cl. H01L 23/00; H01L 21/56; H01L 23/31; H01L 23/498; H01L 25/065; H01L 25/10

(52) U.S. Cl. CPC H01L 24/32; H01L 21/565; H01L 23/3107; H01L 23/49838; H01L 24/16; H01L 24/27; H01L 24/73; H01L 24/81; H01L 25/0652; H01L 25/0655; H01L 25/105; H01L 2224/16227; H01L 2224/27515; H01L 2224/2784; H01L 2224/32225; H01L 2224/73204; H01L 2224/81203; H01L 2225/1023; H01L 2225/1041; H01L 2225/1058; H01L 2924/3511

(57) ABSTRACT

A package structure includes a first RDL, an adhesive layer and a first electronic component. Upper bumps and conductive pads are provided on a first upper surface and a first lower surface of the first RDL, respectively. The adhesive layer is located on the first upper surface of the first RDL and surrounds the upper bumps. The first electronic component is mounted on the adhesive layer and includes conductors which are visible from an active surface of the first electronic component and joined to the upper bumps, the active surface of the first electronic component faces toward the first upper surface of the first RDL. Two adhesive surfaces of the adhesive layer are adhered to the first upper surface of the first RDL and the active surface of the first electronic component, respectively.

### FIELD OF THE INVENTION

This invention relates to a package structure and a method of manufacturing the same, and more particularly to a package structure with adhesive layer and a method of manufacturing the same.

### BACKGROUND OF THE INVENTION

Semiconductor package with higher density is the developmental trend to enhance signal transmission rate and power density of semiconductor chip. In conventional semiconductor package, dies can be stacked with available signal transmission by through-silicon vias (TSV), and dies can be provided in the same package by redistribution layer (RDL). During thermal compression bonding of dies and RDL, stress usually causes die warpage to lower bonding strength, and solder bumps on the die and bonding bumps of RDL may be mismatched to reduce bump contacting area and bonding strength.

### SUMMARY

One object of the present invention is to use an adhesive layer to adhere a redistribution layer and an electronic component together so as to improve bonding strength between the two components greatly for more complex package structure.

A package structure of the present invention includes a first redistribution layer (RDL), an adhesive layer and a first electronic component. Upper bumps are provided on a first upper surface of the first RDL, and conductive pads are provided on a first lower surface of the first RDL. The adhesive layer is located on the first upper surface of the first RDL and surrounds the upper bumps. The first electronic component is mounted on the adhesive layer and includes conductors which are exposed from an active surface of the first electronic component and joined to the upper bumps. The active surface of the first electronic component faces toward the first upper surface of the first RDL. One adhesive surface of the adhesive layer is adhered to the first upper surface of the first RDL, and the other adhesive surface of the adhesive layer is adhered to the active surface of the first electronic component.

A method of manufacturing a package structure of the present invention includes the steps as follows. A first RDL is provided, upper bumps are provided on a first upper surface of the first RDL, and conductive pads are provided on a first lower surface of the first RDL. An adhesive layer is formed on the first RDL and located on the first upper surface of the first RDL to surround the upper bumps. The adhesive layer is planarized to lead the upper bumps to be exposed on the adhesive layer. A first electronic component is mounted on the adhesive layer and includes an active surface which is facing toward the first upper surface of the first RDL and conductors which are exposed on the active surface. The first electronic component is bonded to the first RDL by thermal compression to allow the conductors to be joined to the upper bumps. During thermal compression bonding, two adhesive surfaces of the adhesive layer are adhered to the first upper surface of the first RDL and the active surface of the first electronic component, respectively.

In the present invention, the adhesive strength between the first RDL and the first electronic component is improved substantially because the first RDL and the first electronic component are adhered together with the adhesive layer. As a result, the package structure can be designed with more complexity and improved compactness to increase signal transmission rate and power density.

### DESCRIPTION OF THE DRAWINGS

FIG. 1 is a cross-section view diagram illustrating a package structure in accordance with a first embodiment of the present invention.

FIG. 2 is a cross-section view diagram illustrating a package structure in accordance with a second embodiment of the present invention.

FIG. 3 is a cross-section view diagram illustrating a package structure in accordance with a third embodiment of the present invention.

FIG. 4 is a cross-section view diagram illustrating a package structure in accordance with a fourth embodiment of the present invention.

FIGS. 5a, 5b and 5c are cross-section view diagrams illustrating procedures of a method of manufacturing the package structure in accordance with the first embodiment of the present invention.

FIGS. 6a, 6b and 6c are cross-section view diagrams illustrating procedures of a method of manufacturing the package structure in accordance with the third embodiment of the present invention.

FIGS. 7a, 7b and 7c are cross-section view diagrams illustrating procedures of a method of manufacturing the package structure in accordance with the fourth embodiment of the present invention.

### DETAILED DESCRIPTION OF THE INVENTION

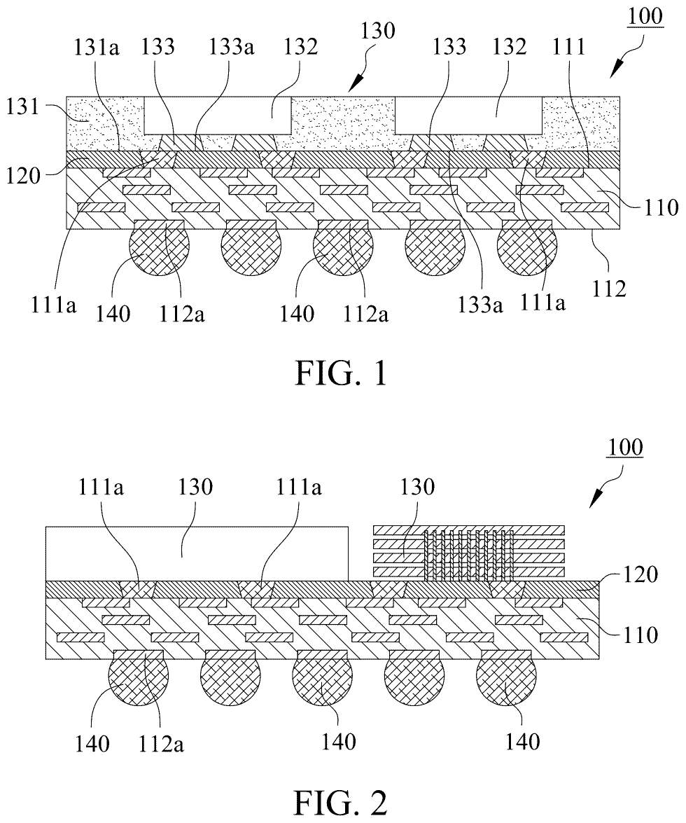

With reference to FIG. 1, a package structure 100 in accordance with a first embodiment of the present invention includes a first redistribution layer (RDL) 110, an adhesive 120 and a first electronic component 130. A first upper surface 111 of the first RDL includes a plurality of upper bumps 111a, and a first lower surface 112 of the first RDL 110 includes a plurality of conductive pads 112a. Preferably, the first RDL 110 includes at least one circuit layer and an insulation layer, the upper bumps 111a are electrically connected to the conductive pads 112a through the circuit layer, and the insulation layer is provided for carrying and insulation of the circuit layer. Patterns of the first RDL 110 are various and not important feature of the present invention, so the first RDL 110 is simplified to multiple blocks in the diagrams.

The adhesive layer 120 is provided on the first upper surface 111 of the first RDL 110 and surrounds the upper bumps 111a. In the first embodiment, the adhesive layer 120 is formed by curing an organic adhesive material, and preferably, the thermal expansion coefficient of the adhesive layer 120 is similar to that of the insulation layer of the first RDL 110 thereby avoiding warpage or distortion caused by uneven thermal expansion in subsequent thermal processes. The first electronic component 130 is mounted on the adhesive layer 120 and includes a plurality of conductors which are exposed from an active surface of the first electronic component 130 and joined to the upper bumps 111a one to one. The active surface of the first electronic component 130 faces towards the first upper surface 111 of the first RDL 110. One adhesive surface of the adhesive layer 120 is adhered to the first upper surface 111 of the first RDL 110, and the other adhesive surface of the adhesive layer 120 is adhered to the active surface of the first electronic component 130, respectively.

With reference to FIG. 1, the first electronic component 130 of the first embodiment includes a first encapsulate 131, a first die 132 and a plurality of solder bumps 133 located on the first die 132. The first die 132 and the first solder bumps 133 are surrounded by the first encapsulate 131, and a first connection surface 133a of each of the solder bumps 133 is visible from an exposed surface 131a of the first encapsulate 131. In this embodiment, the active surface of the first electronic component 130 is the exposed surface 131a of the first encapsulate 131, and the conductors of the first electronic component 130 are the first solder bumps 133. Preferably, the first encapsulate 131 is made of epoxy molding compound (EMC), and the solder bumps 133 are made of a metallic or alloy material.

In this embodiment, each of the first solder bumps 133 of the first electronic component 130 is eutectic bonded to one of the upper bumps 111a of the first RDL 110 by thermal compression. The adhesive layer 120 is heated to be melted during thermal compression bonding, thereby adhering the exposed surface 131a of the first electronic component 130 and the first upper surface 111 of the first RDL 110 together, and the adhesive layer 120 is cooled and cured after thermal compression bonding. The solvent in the adhesive layer 120 is volatilized by heating, thus the hardness of the adhesive layer 120 is increased. In this embodiment, the first electronic component 130 is not only eutectic bonded to the first RDL 110 using metal bumps, but also adhered to the first RDL 110 by the adhesive layer 120, consequently, the adhesive strength between the first electronic component 130 and the first RDL 110 can be enhanced substantially to avoid warpage of the first electronic component 130 during thermal compression bonding, and the package structure 100 with more complex designs is available.

Referring to FIG. 1 again, the package structure 100 further includes a plurality of conductive components 140 which are located on the first lower surface 112 of the first RDL 110. Each of the conductive components 140 is connected to one of the conductive pads 112a such that the package structure 100 and other electronic component (e.g. circuit board or flexible circuit board) can be connected with each other for signal transmission in two-way. The conductive components 140 are solder balls in this embodiment, and they may be solder bumps, anisotropic conductive film (ACF) or wire bonding in other embodiments.

With reference to FIG. 1, the first encapsulate 131 includes two first dies 132 in the first embodiment, but it may include one or more than two first dies 132 in other embodiments, the amount of the first die 132 is not restricted in the present invention. A second embodiment of the present invention is shown in FIG. 2, different to the first embodiment, there are two first electronic components 130 on the first RDL 110 in the second embodiment. The two first electronic components 130 may be CPU chip and memory chip which can be electrically connected with each other through the first RDL 110 or connected to the conductive components 140 located on the first upper surface 112 of the first RDL 110 for the purpose of system in package (SiP).

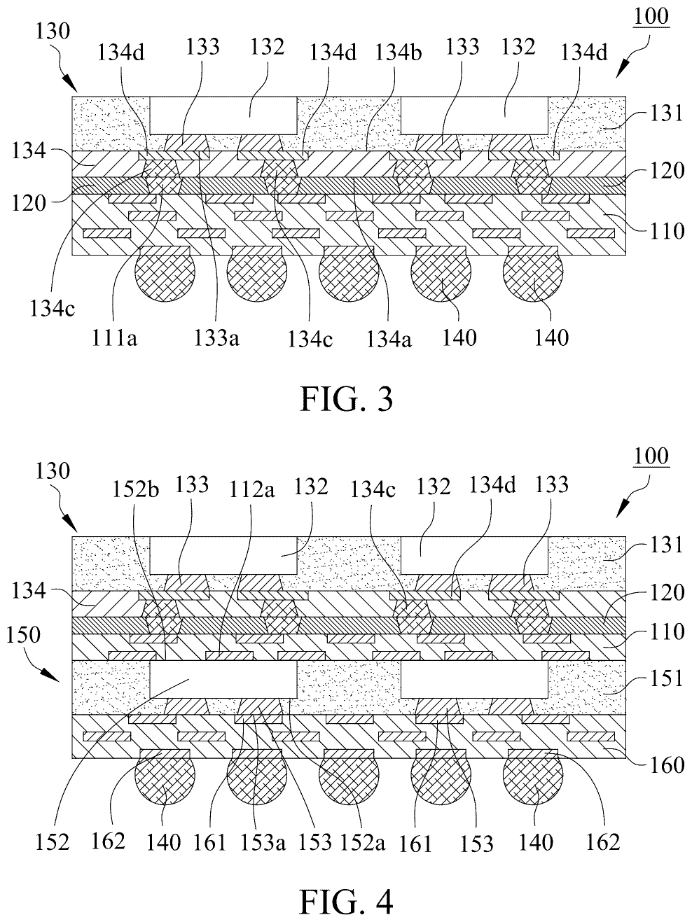

With reference to FIG. 3, different from the first embodiment, the first electronic component 130 of a third embodiment of the present invention further includes a second RDL 134. A plurality of lower RDL pads 134c arranged on a second lower surface 134a of the second RDL 134 are connected to the upper bumps 111a, and a plurality of upper RDL pads 134d arranged on a second upper surface 134b of the second RDL 134 are connected to the first solder bumps 133. In the third embodiment, the active surface of the first electronic component 130 is the second lower surface 134a of the second RDL 134, and the conductors of the first electronic component 130 are the lower RDL pads 134c. Because of the second RDL 134, the contact area between the lower RDL pads 134c and the upper bumps 111a are increased for flexible arrangements of the first electronic component 130 and the first RDL 110. Preferably, the second RDL 134 further includes an insulator which is provided for supporting and insulation and is made of an organic adhesive material or an organic polymer with a thermal expansion coefficient similar to that of the adhesive layer 120. Likewise, it is able to prevent the second RDL 134 and the adhesive layer 120 from being separated due to difference of thermal expansion coefficient during thermal compression bonding.

FIG. 4 represents a fourth embodiment of the present invention. The difference between the third and fourth embodiments is that the package structure 100 of the fourth embodiment further includes a second electronic component 150 and a third RDL 160. The second electronic component 150 includes a second encapsulate 151, a second die 152 and a plurality of second solder bumps 153. Both sides of the second solder bumps 153 are joined to a lower conduction surface 152a of the second die 152 and upper conductive pads 161 of the third RDL 160, respectively. The second encapsulate 151 surrounds the second die 152 and the second solder bumps 153. An upper conduction surface 152b of the second die 152 is exposed on the top of the second encapsulate 151, and a second connection surface 153a of each of the second solder bumps 153 is exposed on the bottom of the second encapsulate 151. The upper conduction surface 152b of the second die 152 is connected to the conductive pads 112a of the first RDL 110. In this embodiment, the conductive components 140 are joined to a plurality of lower conductive pads 162 of the third RDL 160 for transmitting signals externally from the first electronic component 130 and the second electronic component 150.

In the present invention, the adhesive layer 120 is provided to adhere the first RDL 110 and the first electronic component 130, thereby highly enhancing the adhesive strength between the first RDL 110 and the first electronic component 130. Accordingly, the package structure 100 can be designed with more complexity and improved compactness to increase signal transmission rate and power density.

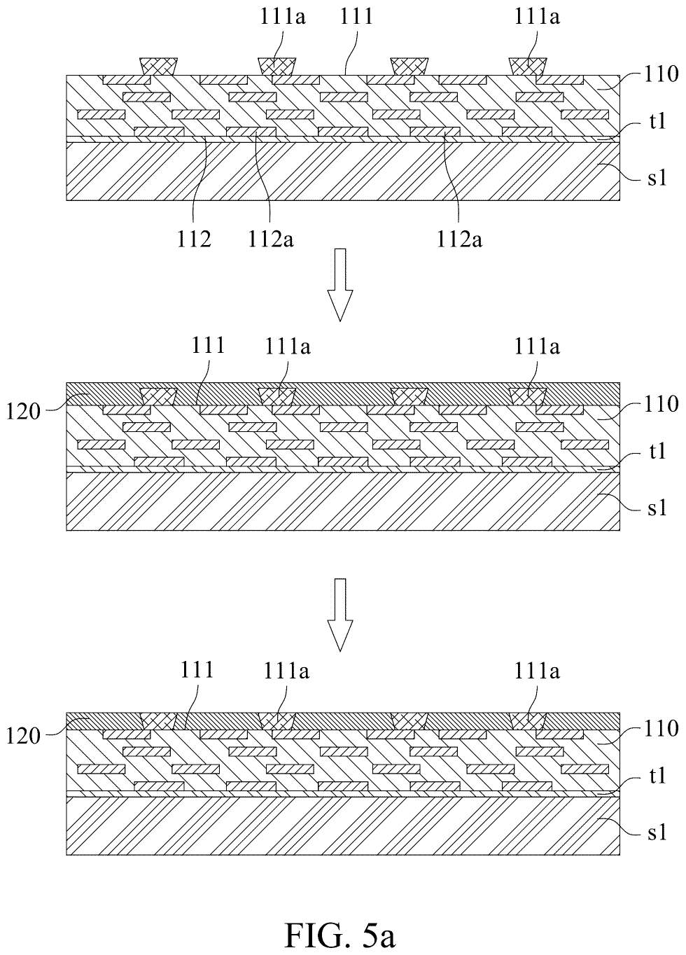

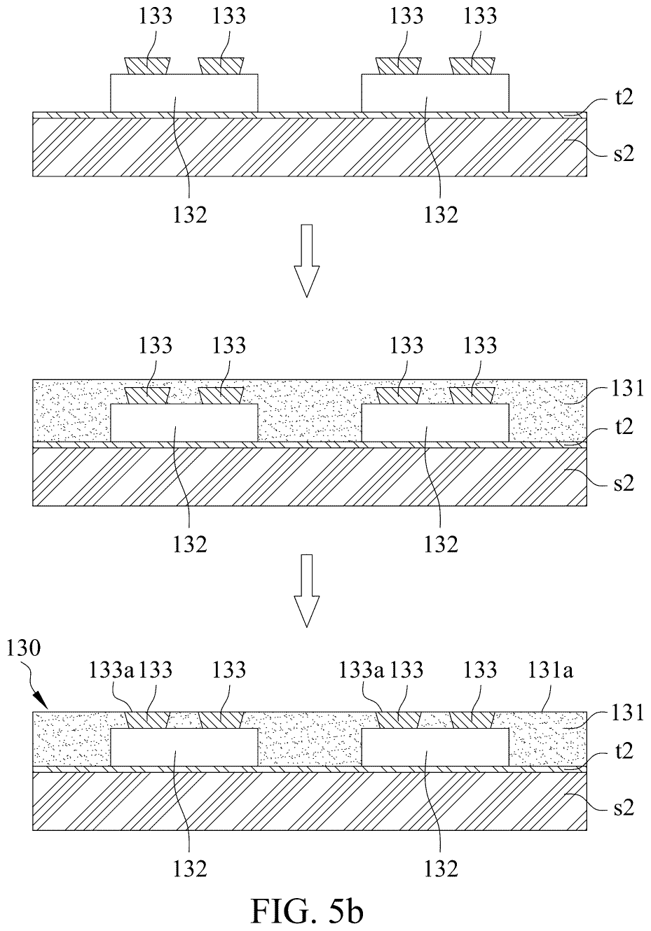

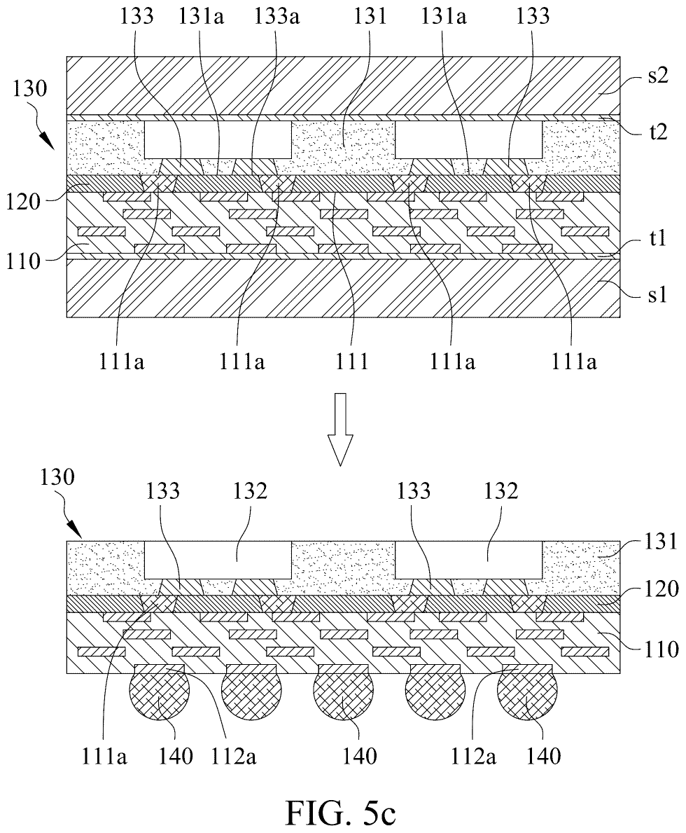

FIGS. 5a, 5b and 5c show the procedures of a method of manufacturing the package structure 100 of the first embodiment of the present invention. As shown in FIG. 5a, a first RDL 110 is provided and adhered onto a first carrier s1 with a first adhesive t1. A first upper surface 111 of the first RDL 110 includes a plurality of upper bumps 111a, and a first lower surface 112 of the first RDL 110 includes a plurality of conductive pads 112a. An adhesive layer 120 is provided on the first RDL 110 and located on the first upper surface 111 of the first RDL 110 to surround the upper bumps 111a. In the first embodiment, an organic adhesive material is applied onto the first RDL 110, and it is heated and then cooled to become the cured adhesive layer 120. Next, the adhesive layer 120 is planarized to allow the upper bumps 111a to be exposed from the adhesive layer 120. Preferably, the cured adhesive layer 120 is planarized by fly-cutting in this embodiment.

FIG. 5b illustrates the procedures of manufacturing a first electronic component 130 of the first embodiment of the present invention. Firstly, a plurality of first dies 132 are disposed on a second carrier s2 using a second adhesive t2, and a plurality of first solder bumps 133 are provided on each of the first dies 132. Then, a first encapsulate 131 is formed to cover the first dies 132 and the first solder bumps 133, and the first encapsulate 131 is planarized to form an exposed surface 131a on the top of the first encapsulate 131, where a first connection surface 133a of each of the first solder bumps 133 is exposed. In this embodiment, the exposed surface 131a of the first encapsulate 131 is the active surface of the first electronic component 130, and the first solder bumps 133 are the conductors of the first electronic component 130.

With reference to FIG. 5c, after the planarization procedure of the adhesive layer 120 as shown in FIG. 5a and the manufacturing procedure of the first electronic component 130 as shown in FIG. 5b, the first electronic component 130 is upside down and placed on the adhesive layer 120 to lead the exposed surface 131a of the first encapsulate 131 and the first connection surface 133a of each of the first solder bumps 133 facing toward the first upper surface 111 of the first RDL 110, and then a thermal compression bonding of the first electronic component 130 to the first RDL 110 is performed to allow the first solder bumps 133 to be eutectic bonded to the upper bumps 111a. During the thermal compression bonding, the adhesive layer 120 is heated to be melted again and its two adhesive surfaces are adhered to the first upper surface 111 of the first RDL 110 and the exposed surface 131a of the first encapsulate 131, respectively. And the melted adhesive layer 120 is cooled and cured again after the thermal compression bonding.

Depending on property of the organic adhesive material used to make the adhesive layer 120, if the solvent in the organic adhesive material cannot be volatilized completely owing to the temperature of the thermal compression bonding is not high enough, the adhesive layer 120 has to be heated again after the thermal compression bonding to allow the solvent remained in the organic adhesive material to be volatilized completely, and then the adhesive layer 120 is cooled and cured. Next, the first adhesive t1 and the first carrier s1 are removed, and a plurality of conductive components 140 are provided on the first lower surface 112 of the first RDL 110 to connect to the conductive pads 112a. And finally, the second adhesive t2 and the second carrier s2 are removed to complete the manufacture of the package structure 100 of the first embodiment of the present invention.

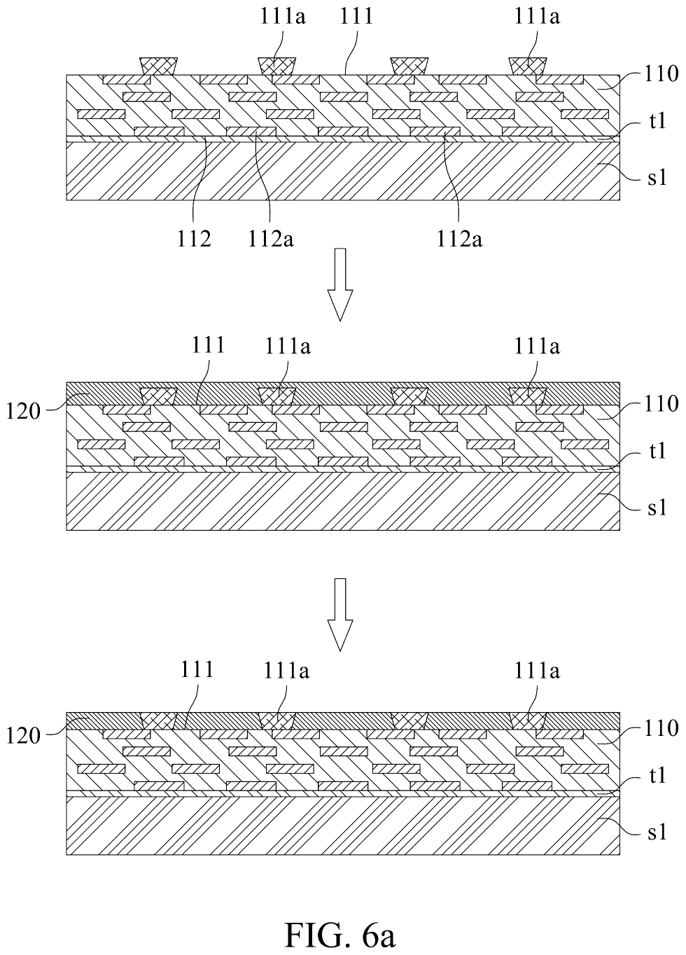

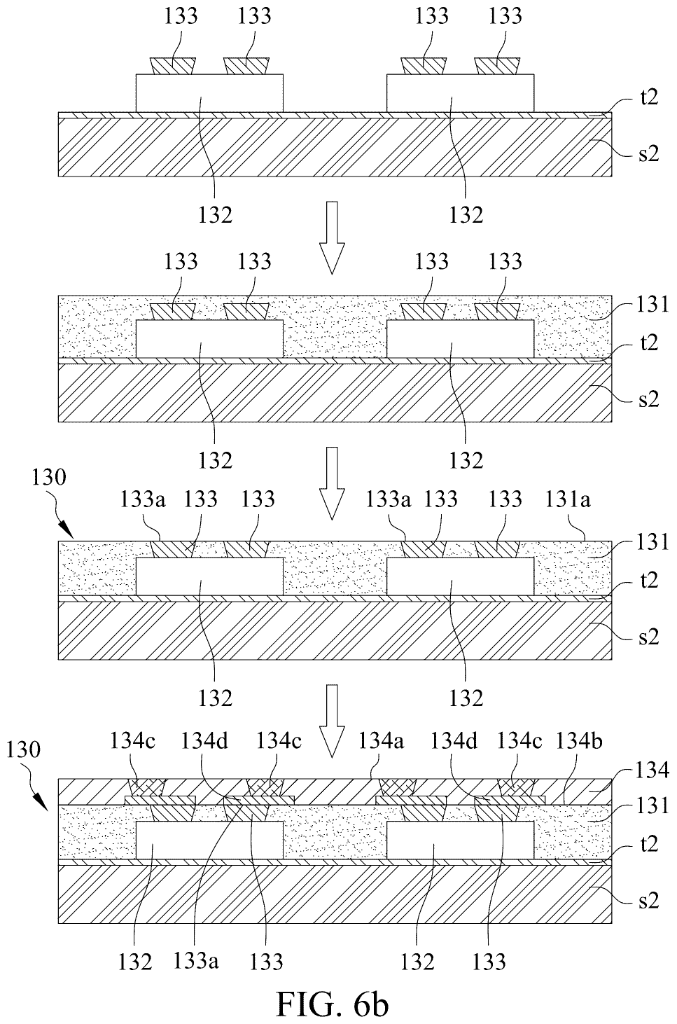

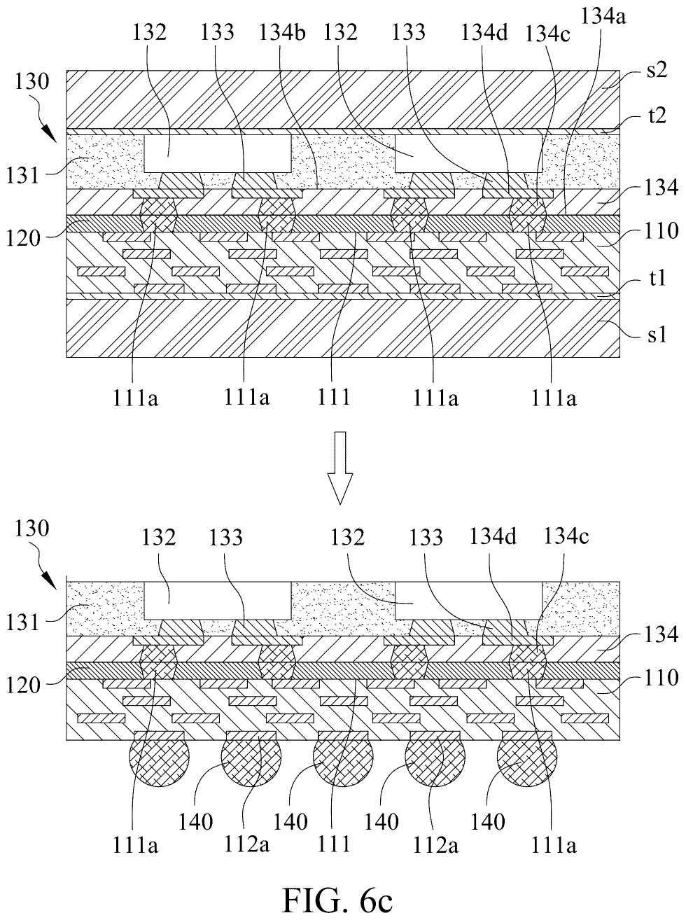

FIGS. 6a, 6b and 6c are provided to illustrate the procedures of a method of manufacturing the package structure 100 of the third embodiment of the present invention. The procedures shown in FIG. 6a are identical to that shown in FIG. 5a, so they will be not repeated here. The procedures of manufacturing a first electronic component 130 of the third embodiment of the present invention are shown in FIG. 6b. A plurality of first dies 132 are mounted on a second carrier s2 using a second adhesive t2, and a plurality of first solder bumps 133 are provided on each of the first dies 132. A first encapsulate 131 is formed to cover the first dies 132 and the first solder bumps 133. And next, the first encapsulate 131 is planarized to allow an exposed surface 131a to be exposed on the top of the first encapsulate 131, a first connection surface 133a of each of the first solder bumps 133 is visible from the exposed surface 131a of the first encapsulate 131. And finally, a second RDL 134 is formed on the exposed surface 131a of the first encapsulate 131, and a plurality of upper RDL pads 134d located on a second upper surface 134b of the second RDL 134 are connected to the first solder bumps 133. In the third embodiment, the active surface of the first electronic component 130 is a second lower surface 134a of the second RDL 134, and the conductors of the first electronic component 130 are a plurality of lower RDL pads 134c of the second lower surface 134a of the second RDL 134.

With reference to FIG. 6c, after the procedures as shown in FIGS. 6a and 6b, the first electronic component 130 is flip mounted on the adhesive layer 120, and the second lower surface 134a of the second RDL 134 is faced toward the first upper surface 111 of the first RDL 110. Thermal compression bonding of the first electronic component 130 and the first RDL 110 is performed to allow the lower RDL pads 134c of the second lower surface 134a of the second RDL 134 to be eutectic bonded to the upper bumps 111a. The adhesive layer 120 is heated and melted again during the thermal compression bonding, and its two adhesive surfaces are adhered to the first upper surface 111 of the first RDL 110 and the second lower surface 134a of the second RDL 134. After the thermal compression bonding, the adhesive layer 120 is cooled and then cured again.

Finally, the first adhesive t1 and the first carrier s1 are removed, a plurality of conductive components 140 are provided on the first lower surface 112 of the first RDL 110 to join with the conductive pads 112a, and the second adhesive t2 and the second carrier s2 are removed to obtain the package structure 100 of the third embodiment of the present invention.

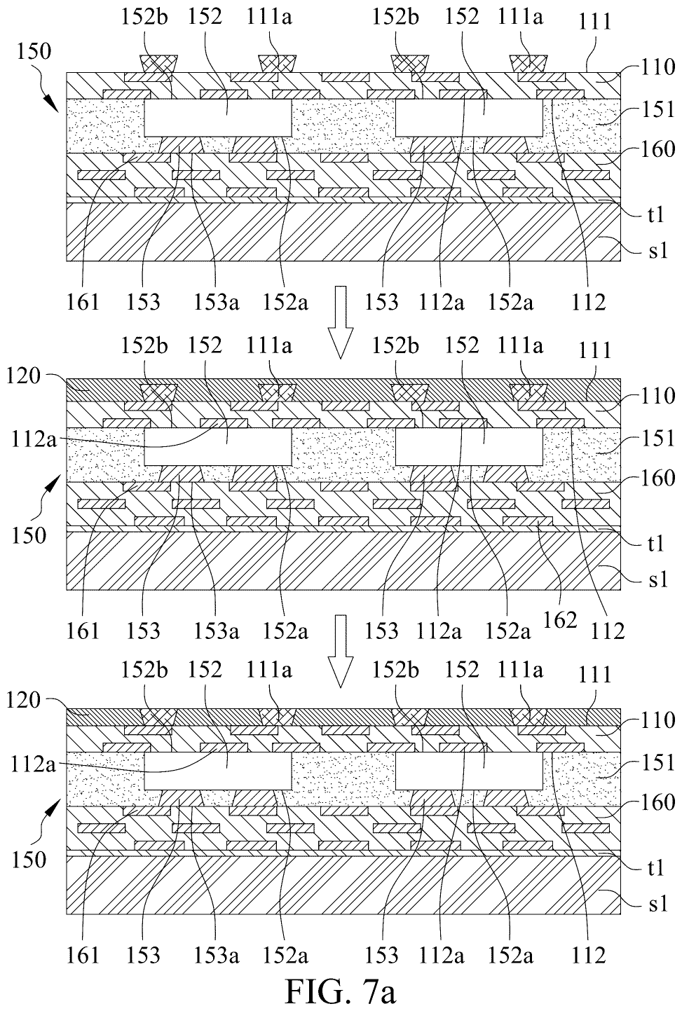

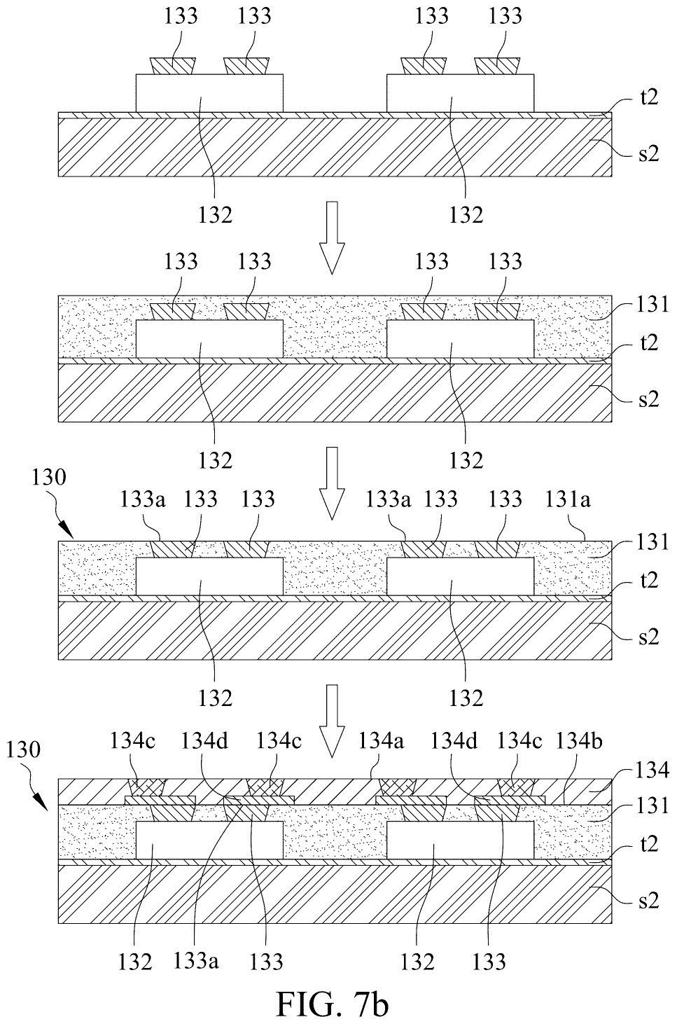

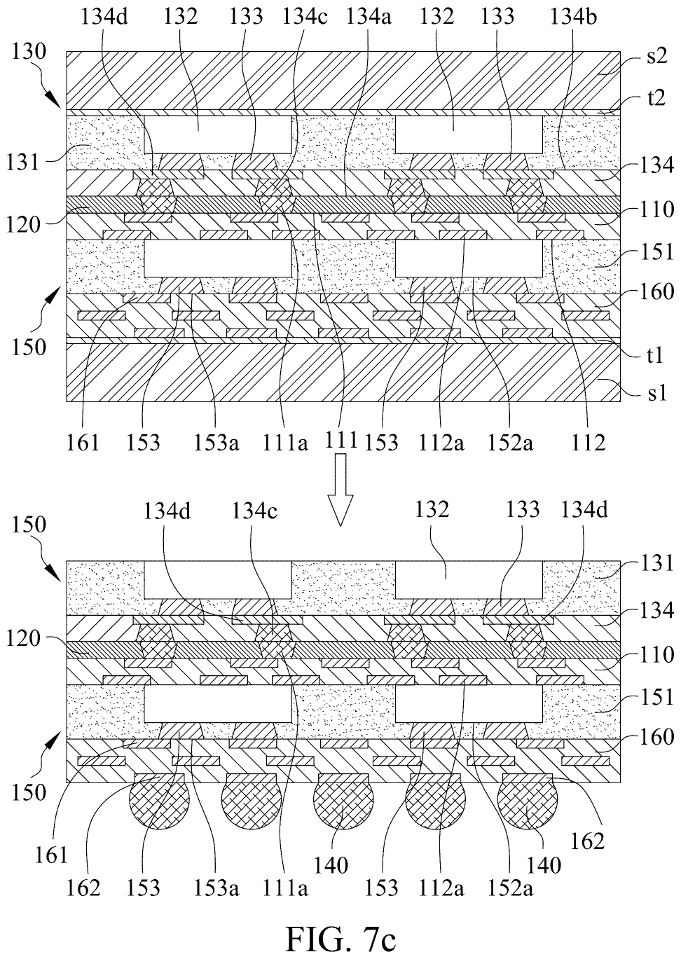

The procedures of a method of manufacturing the package structure 100 in accordance with the fourth embodiment of the present invention are shown in FIGS. 7a, 7b and 7c. The procedures shown in FIG. 7b are similar to that shown in FIG. 6b, so no more description here. With reference to FIG. 7a, a first RDL 100 is provided, and in this embodiment, the first RDL 110 is provided on a second electronic component 150 and a third RDL 160. The second electronic component 150 includes a second encapsulate 151, a second die 150 and a plurality of second solder bumps 153. The second die 152 has a lower conduction surface 152a and an upper conduction surface 152b, both sides of the second solder bumps 153 are connected to the lower conduction surface 152a of the second die 152 and a plurality of upper conductive pads 161 of the third RDL 160, respectively. The second encapsulate 151 surrounds the second die 152 and the second solder bumps 153, the upper conduction surface 152b of the second die 152 and a second connection surface 153a of each of the second solder bumps 153 are exposed from the second encapsulate 151, and the upper conduction surface 152b of the second die 152 is connected to the conductive pads 112a of the first RDL 110. The first RDL 110, the second electronic component 150 and the third RDL 160 are disposed on a first carrier s1 by a first adhesive t1. After that, an adhesive layer 120 is provided on the first RDL 110 to be located on the first upper surface 111 of the first RDL 110 and surrounds the upper bumps 111a. In the fourth embodiment, an organic adhesive material applied onto the first RDL 110 is heated and then cooled so as to be cured to become the adhesive layer 120. In the end, the adhesive layer 120 is planarized to show the upper bumps 111a. Preferably, the adhesive layer 120 is planarized by fly-cutting.

With reference to FIG. 7c, when the procedures as shown in FIGS. 7a and 7b are complete, the first electronic component 130 is reversed and placed on the adhesive layer 120 to lead the second lower surface 134a of the second RDL 134 facing towards the first upper surface 111 of the first RDL 110, the first electronic component 130 is thermal compression bonded to the first RDL 110 for eutectic bonding between the lower RDL pads 134c on the second lower surface 134a and the upper bumps 111a. During the thermal compression bonding, the adhesive layer 120 is heated and melted again and its two adhesive surfaces are adhered to the first upper surface 111 of the first RDL 110 and a second lower surface 134a of the second RDL 134. The adhesive layer 120 is then cured and solidified after the thermal compression bonding.

The first adhesive t1 and the first carrier s1 are removed, and a plurality of conductive components 140 are provided on a plurality of lower conductive pads 162 of the third RDL 160 to allow each of the conductive components 140 to be joined with one of the lower conductive pads 162. In the end, the second adhesive t2 and the second carrier s2 are removed to get the package structure 100 of the fourth embodiment of the present invention.

In the present invention, the adhesive layer 120 is provided on the first RDL 110 and is melted to adhere the first electronic component 130 and the first RDL 110 during the thermal compression bonding of the first electronic component 130 to the first RDL 110. Accordingly, bonding strength between the first electronic component 130 and the first RDL 111 can be increased substantially, and the package structure 100 with more density and complexity is available.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

What is claimed is:

1. A package structure comprising:
a first redistribution layer (RDL) including a first upper surface and a first lower surface, the first upper surface includes a plurality of upper bumps, and the first lower surface includes a plurality of conductive pads;
an adhesive layer located on the firs upper surface of the first RDL and configured to surround the plurality of upper bumps; and
a first electronic component disposed on the adhesive layer and including an active surface and a plurality of conductors, the active surface faces toward the first upper surface of the first RDL, and each of the plurality of conductors is exposed on the active surface and connected to one of the plurality of upper bumps, wherein two adhesive surfaces of the adhesive layer are configured to be adhered to the first upper surface of the first RDL and the active surface of the first electronic component, respectively.

2. The package structure in accordance with claim 1, wherein the adhesive layer is formed by curing an organic adhesive material.

3. The package structure in accordance with claim 1 further comprising a plurality of conductive components, wherein each of the plurality of conductive components is located on the first lower surface of the first RDL and configured to be connected to one of the plurality of conductive pads.

4. The package structure in accordance with claim 1, wherein the first electronic component further includes a first encapsulate, a first die and a plurality of first solder bumps located on the first die, the first encapsulate is configured to surround the first die and the plurality of first solder bumps, a first connection surface of each of the plurality of first solder bumps is exposed from an exposed surface of the first encapsulate, the exposed surface of the first encapsulate is the active surface of the first electronic component, and the plurality of first solder bumps are the plurality of conductors of the first electronic component.

5. The package structure in accordance with claim 4, wherein the first electronic component further includes a second RDL, the second RDL includes a second lower surface and a second upper surface, a plurality of lower RDL pads of the second lower surface are connected to the plurality of upper bumps, a plurality of upper RDL pads of the second upper surface are connected to the plurality of first solder bumps, the second lower surface of the second RDL is the active surface of the first electronic component, and the plurality of lower RDL pads are the plurality of conductors of the first electronic component.

6. The package structure in accordance with claim 5 further comprising an second electronic component and a third RDL, wherein the second electronic component includes a second encapsulate, a second die and a plurality of second solder bumps, the second die includes a lower conduction surface and an upper conduction surface, both sides of the plurality of second solder bumps are connected to the lower conduction surface of the second die and a plurality of upper conductive pads of the third RDL respectively, the second encapsulate is configured to surround the second die and the plurality of second solder bumps, the upper conduction surface of the second die and a second connection surface of each of the plurality of second solder bumps are exposed from the second encapsulate, the upper conduction surface of the second die is connected to the plurality of conductive pads of the first RDL.

7. The package structure in accordance with claim 6 further comprising a plurality of conductive components, wherein the plurality of conductive components are connected to a plurality of lower conductive pads of the third RDL.

8. A method of manufacturing a package structure comprising the steps of:
providing a first redistribution layer (RDL) including a first upper surface and a first lower surface, the first upper surface includes a plurality of upper bumps, and the first lower surface includes a plurality of conductive pads;
forming an adhesive layer on the first RDL, the adhesive layer is located on the first upper surface of the first RDL and configured to surround the plurality of upper bumps;
planarizing the adhesive layer to allow the plurality of upper bumps to be exposed from the adhesive layer;
disposing a first electronic component on the adhesive layer, the first electronic component includes an active surface facing toward the first upper surface of the first RDL and a plurality of conductors exposed on the active surface; and
performing a thermal compression bonding of the first electronic component and the first RDL to allow each of the plurality of conductors to be connected to one of the plurality of upper bumps, wherein two adhesive surfaces of the adhesive layer are configured to be adhered to the first upper surface of the first RDL and the active surface of the first electronic component, respectively during the thermal compression bonding.

9. The method in accordance with claim 8, wherein the step of forming the adhesive layer on the first RDL further comprises the substeps of:
applying an organic adhesive material on the first RDL; and
heating and cooling the organic adhesive material to cure the organic adhesive material and allow the organic adhesive material to become the adhesive layer.

10. The method in accordance with claim 8, wherein the adhesive layer is planarized by fly-cutting.

11. The method in accordance with claim 8 further comprising the step of heating and cooling the adhesive layer to cure the adhesive layer after the thermal compression bonding of the first electronic component and the first RDL.

12. The method in accordance with claim 8 further comprising the step of disposing a plurality of conductive components on the first lower surface of the first RDL to allow each of the plurality of conductive components to be connected to one of the plurality of conductive pads.

13. The method in accordance with claim 8, wherein the first electronic component is manufactured by the substeps of:
forming a plurality of first solder bumps on a first die;
forming a first encapsulate to cover the first die and the plurality of first solder bumps; and
planarizing the first encapsulate to form an exposed surface on the first encapsulate, a first connection surface of each of the plurality of first solder bumps is exposed from the exposed surface, the exposed surface of the first encapsulate is the active surface of the first electronic component, and the plurality of first solder bumps are the plurality of conductors of the first electronic component.

14. The method in accordance with claim 8, wherein the first electronic component is manufactured by the substeps of:
forming a plurality of first solder bumps on a first die;
forming a first encapsulate to cover the first die and the plurality of first solder bumps;
planarizing the first encapsulate to form an exposed surface on the first encapsulate, a first connection surface of each of the plurality of first solder bumps is exposed from the exposed surface; and
forming a second RDL on the exposed surface of the first encapsulate, the second RDL includes a second lower surface and a second upper surface, a plurality of upper RDL pads of the second upper surface of the second RDL are connected to the plurality of first solder bumps, the second lower surface of the second RDL is the active surface of the first electronic component, and a plurality of lower RDL pads of the second lower surface of the second RDL are the plurality of conductors of the first electronic component, wherein the plurality of lower RDL pads of the second lower surface of the second RDL are connected to the plurality of upper bumps during the thermal compression bonding of the first electronic component and the first RDL.

15. The method in accordance with claim 14, wherein the first RDL is disposed on a second electronic component and a third RDL, the second electronic component includes a second encapsulate, a second die and a plurality of second solder bumps, the second die includes a lower conduction surface and an upper conduction surface, both sides of the plurality of second solder bumps are connected to the lower conduction surface of the second die and a plurality of upper conductive pads of the third RDL respectively, the second encapsulate is configured to surround the second die and the plurality of second solder bumps, the upper conduction surface of the second die and a second connection surface of each of the plurality of second solder bumps are exposed from the second encapsulate, the upper conduction surface of the second die is connected to the plurality of conductive pads of the first RDL.

16. The method in accordance with claim 15 further comprising the step of disposing a plurality of conductive components on a plurality of lower conductive pads of the third RDL to allow each of the plurality of conductive components to be connected to one of the plurality of lower conductive pads.
